(19) United States
(12) Patent Application Publication
(10) Pub. No.: US 2023/0112703 A1
(43) Pub. Date: Apr. 13, 2023

(54) Transparent display panel

(71) Applicant: ProLight Opto Technology Corporation, Taoyuan City (TW)

(72) Inventors: Chen-Lun Hsing Chen, Taoyuan City (TW); Jung-Hao Hung, Taoyuan City (TW); Meng-Ting Hsieh, Taoyuan City (TW)

(73) Assignee: ProLight Opto Technology Corporation, Taoyuan City (TW)

(21) Appl. No.: 17/562,018

(22) Filed: Dec. 27, 2021

(30) Foreign Application Priority Data
Oct. 13, 2021 (TW) 110137990

(51) Int. Cl. H01L 33/56; H01L 33/62; H01L 33/38

(52) U.S. Cl. CPC H01L 33/56; H01L 33/62; H01L 33/38

(57) ABSTRACT

The invention provides a transparent display panel. The display panel includes an encapsulated integrated circuit, a front surface and a back surface of the encapsulated integrated circuit both comprise a plurality of electrodes, and a light-emitting element which is positioned on the front surface of the encapsulated integrated circuit. When views in a top view, the light-emitting element partially overlaps the encapsulated integrated circuit from a vertical direction, and is electrically connected with the electrodes on the front surface of the encapsulated integrated circuit.

### BACKGROUND OF THE INVENTION

### 1. Field of the Invention

The present invention relates to a transparent display panel, in particular to a transparent display panel in which light-emitting elements and encapsulated integrated circuits are stacked, which has the advantage of smaller element area.

### 2. Description of the Prior Art

With the development of display technology, in addition to ordinary displays, the industry also began to research and develop displays with light-emitting elements made on transparent substrates (such as glass), also known as transparent display panels, which have the functions of both light transmission and display. When the light-emitting element is not activated, it can be used as transparent glass, while when the light-emitting element is activated, for example, it can generate patterns on the transparent glass to display trademarks or advertisements.

FIG. 1 shows a cross-sectional structure diagram of a conventional transparent display panel. As shown in FIG. 1, an encapsulated integrated circuit IC is used as a controller to connect light-emitting elements 10 (such as light-emitting diodes), which are connected by a plurality of wires 12. In which the above components are located on an opaque carrier plate 14 (such as PCB), and then the opaque carrier plate 14 is located on a transparent substrate 16 (such as glass). In the above structure, when the number of light-emitting elements 10 is increased, the area of the opaque carrier plate 14 will also increase to accommodate more light-emitting elements 10. However, when the area of the opaque carrier plate 14 increases, but the area of the transparent substrate 16 (such as glass or windows) remains unchanged, the light-transmitting area of the transparent substrate 16 will decrease, which will further affect the total light transmittance (that is, the light-transmitting area of the transparent substrate/the total area of the transparent substrate).

Therefore, a new structure is needed, which can improve the luminous efficiency of transparent display panels and maintain good light transmittance.

### SUMMARY OF THE INVENTION

The invention provides a transparent display panel, which comprises a encapsulated integrated circuit, wherein a front surface and a back surface of the encapsulated integrated circuit both contain a plurality of electrodes, and a light-emitting element located on the front surface of the encapsulated integrated circuit, which partially overlaps with the encapsulated integrated circuit from a vertical direction and is electrically connected with the electrodes on the front surface of the encapsulated integrated circuit.

The present invention is characterized in that the pins (electrodes) of the encapsulated integrated circuit (IC) are designed to the top and back surfaces of the encapsulated integrated circuit structure, and light-emitting elements (such as light-emitting diodes) are stacked on the encapsulated integrated circuit without occupying other space. In most cases, the light-emitting element can be directly electrically connected to the pins (electrodes) of the encapsulated integrated circuit, so there is no need to form additional wires. According to the invention, the stacked structure of the encapsulated integrated circuit and the light-emitting element can be directly arranged on the transparent substrate, so that the opaque carrier plate is omitted, the occupied area of the element can be greatly reduced, and the total light transmittance of the transparent display panel can be obviously improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional view of a conventional transparent display panel.

FIG. 2 is a sectional view of a transparent display panel according to the first preferred embodiment of the present invention.

FIG. 3 is a sectional view of a transparent display panel according to the second preferred embodiment of the present invention.

FIG. 4 is a sectional view of a transparent display panel according to the third preferred embodiment of the present invention.

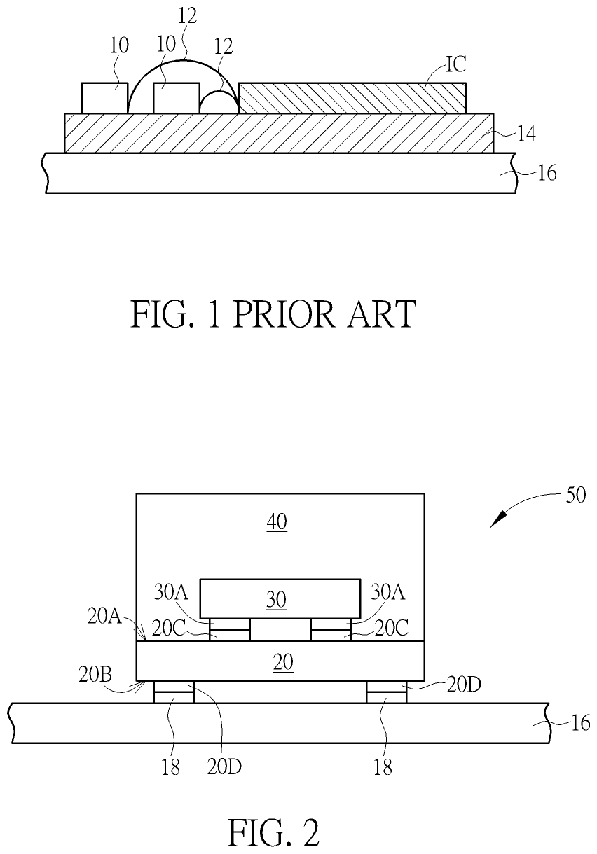

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the Figures are only for illustration and the Figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Please refer to FIG. 2, which shows a sectional structure diagram of a transparent display panel according to the first preferred embodiment of the present invention. As shown in FIG. 2, firstly, a transparent substrate 16 is provided, for example, glass, and transparent wires 18 made of transparent conductive materials (such as indium tin oxide (ITO)) can be plated on the transparent substrate 16, the transparent substrate 16 can be used as the substrate of a transparent display panel, for example, the transparent glass for luminous windows, but the present invention is not limited to this.

Next, an encapsulated integrated circuit (IC) 20 is formed on the transparent substrate 16. It should be noted that the internal structure of the encapsulated integrated circuit 20 in this embodiment is similar to that of the conventional encapsulated integrated circuit, including many logic elements such as switching elements, which can be used as a controller. However, in this embodiment, the pins (or electrodes) of the encapsulated integrated circuit 20 are not located on both sides as in the conventional encapsulated integrated circuit, but on the front surface 20A and the back surface 20B of the encapsulated integrated circuit 20. That is, by designing the pins of the encapsulated integrated circuit 20 to extend from the front surface 20A and the back surface 20B, a plurality of conductive electrodes 20C and 20D are left on the front surface 20A and the back surface 20B, respectively, for connecting other electronic components (for example, for connecting light-emitting elements, etc.).

Then, at least one light-emitting element 30 is formed, for example, a light-emitting diode, or further comprises an organic light-emitting diode (OLED), a mini light-emitting diode (mini LED), a micro LED or a quantum dot LED, but it is not limited thereto. The light-emitting element 30 can emit monochromatic or multi-color mixed light, such as red light, blue light, green light or other mixed light (white light, etc.) composed of multiple colors, but the present invention is not limited thereto. It should be noted that the light-emitting elements 30 in this embodiment are directly arranged and stacked on the encapsulated integrated circuit 20. Preferably, the pins 30A of the light-emitting elements 30 can directly contact and electrically connect with the electrodes 20C above the front surface 20A of the encapsulated integrated circuit 20. In other words, when designing the structure of the encapsulated integrated circuit 20, the electrodes 20C of the encapsulated integrated circuit 20 can be designed to conform to the position arrangement of the pins 30A of the light-emitting elements 30. In this way, the light-emitting elements 30 can be directly mounted on the electrodes 20C of the front surface 20A of the encapsulated integrated circuit 20, and since their positions coincide with each other, there is no need to provide additional wires to connect with each other.

In some embodiments, one encapsulated integrated circuit 20 can be mounted with single or multiple light-emitting elements 30, and the present invention does not limit the number of light-emitting elements 30 mounted on one encapsulated integrated circuit 20.

Next, a protective layer 40 is formed to cover the encapsulated integrated circuit 20 and the light-emitting elements 30 mounted on the encapsulated integrated circuit 20, the protective layer 40 comprises transparent insulating materials such as silicone or epoxy resin. The protective layer 40 can be used to fix the position of the light-emitting element 30, and can prevent external dust or moisture from contacting the light-emitting element 30 and the encapsulated integrated circuit 20, so as to protect the element.

After forming the protective layer 40, the transparent substrate 16, the encapsulated integrated circuit 20, the light-emitting elements 30 and the protective layer 40 together form a transparent display panel 50, the transparent display panel 50 includes the light-emitting elements 30 stacked on the encapsulated integrated circuit 20. In addition, the encapsulated integrated circuit 20 of the transparent display panel 50 is directly mounted on the transparent substrate 16 containing the transparent wires 18 (the transparent wires 18 are electrically connected by the electrodes 20D of the encapsulated integrated circuit 20), and there is no need to additionally form an opaque carrier plate to support the encapsulated integrated circuit 20 and the light-emitting elements 30, so that part of the manufacturing processes can be omitted and the cost can be saved. Besides, the area occupied by the elements can be reduced to improve the overall transmittance of the transparent display panel.

The following description will detail the different embodiments of the transparent display panel of the present invention. To simplify the description, the following description will detail the dissimilarities among the different embodiments and the identical features will not be redundantly described. In order to compare the differences between the embodiments easily, the identical components in each of the following embodiments are marked with identical symbols.

In the above embodiment, since the light-emitting element 30 directly contacts the electrode 20C of the encapsulated integrated circuit 20, there is no need to form additional wires to connect the encapsulated integrated circuit 20 with the light-emitting element 30. However, in other embodiments of the present invention, wires can be formed as required to connect the encapsulated integrated circuit 20 and the light-emitting element 30. Please refer to FIG. 3, which shows the sectional structure of a transparent display panel according to the second preferred embodiment of the present invention. As shown in FIG. 3, this embodiment also includes a transparent substrate 16 with transparent wires 18, and an encapsulated integrated circuit 20 is located on the transparent substrate 16. The front surface 20A of the encapsulated integrated circuit 20 includes electrodes 20C, and the back surface 20B of the encapsulated integrated circuit 20 includes electrodes 20D and is electrically connected with the transparent wires 18. It should be noted that in this embodiment, although the light-emitting element 30 is also stacked on the encapsulated integrated circuit 20, the pin 30A of the light-emitting element 30 is not directly located on the electrode 20C, but a wire 32 is additionally formed to connect the encapsulated integrated circuit 20 and the light-emitting element 30. Then, a protective layer 40 is formed to cover the light-emitting element 30 and the encapsulated integrated circuit 20. The advantage of this embodiment is that when the position of the electrode 20C on the encapsulated integrated circuit 20 does not match the position of the pin 30A of the light-emitting element 30, the wire 32 can still be used to connect the encapsulated integrated circuit 20 with the light-emitting element 30. In this way, the flexibility of the arrangement of the light-emitting elements 30 can be improved.

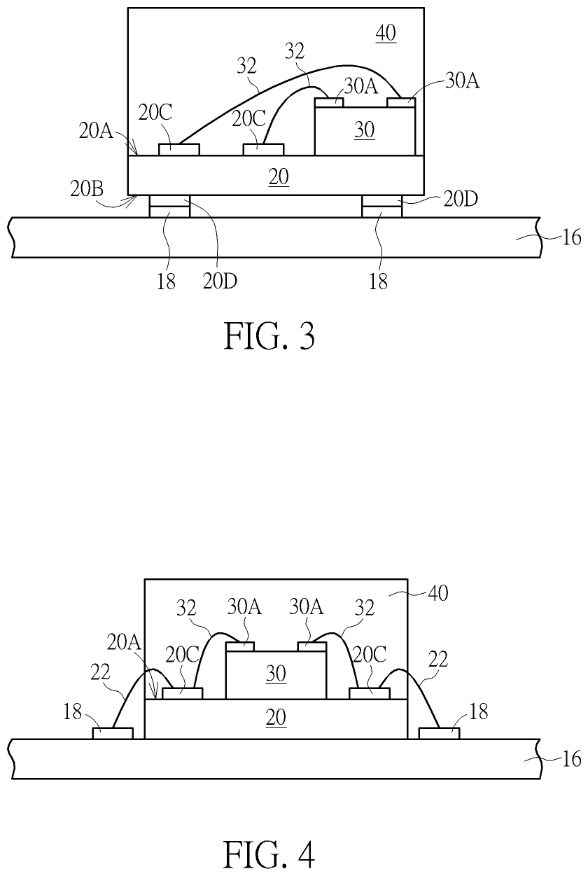

In other embodiments, please refer to FIG. 4, which shows the sectional structure of a transparent display panel according to the third preferred embodiment of the present invention. As shown in FIG. 4, this embodiment also includes a transparent substrate 16, on which transparent wires 18 are included, an encapsulated integrated circuit 20 is located on the transparent substrate 16, and the front surface 20A of the encapsulated integrated circuit 20 includes electrodes 20C. It should be noted that in this embodiment, the back surface of the encapsulated integrated circuit 20 does not contain electrodes, but the electrodes 20C on the encapsulated integrated circuit 20 and the transparent wires 18 on the transparent substrate 16 below can be electrically connected by wires 22. Similarly, the light-emitting element 30 can also be provided with the pins 30A on the front surface, so that the light-emitting element 30 and the encapsulated integrated circuit 20 can also be connected with each other by wires 32. Then, a protective layer 40 is formed to cover the light-emitting element 30 and the encapsulated integrated circuit 20. The advantage of this embodiment is that the encapsulated integrated circuit 20 only forms one-sided electrode 20C, so it is easier to manufacture in the manufacturing process. In this embodiment, because the light-emitting elements 30 are also stacked on the encapsulated integrated circuit 20, the efficiency of saving area and increasing overall light transmittance can also be achieved.

Based on the above description and drawings, the present invention provides a transparent display panel, which includes an encapsulated integrated circuit 20, a front surface 20A and a back surface 20B of the encapsulated integrated circuit 20 both include a plurality of electrodes 20C and 20D, and a light-emitting element 30 located on the front surface 20A of the encapsulated integrated circuit 20. Seen from a vertical direction, the light-emitting element 30 partially overlaps with the encapsulated integrated circuit 20 and is electrically connected with the electrodes 20C on the front surface 20A of the encapsulated integrated circuit 20.

In some embodiments of the present invention, a protective layer 40 is further included to cover the front surface 20A of the encapsulated integrated circuit 20 and the light-emitting element 30.

In some embodiments of the present invention, the material of the protective layer 40 includes transparent silicone or epoxy resin.

In some embodiments of the present invention, a transparent substrate 16 is further included, and the back surface 20B of the encapsulated integrated circuit 20 is in direct contact with a plurality of transparent wires 18 on the transparent substrate 16.

In some embodiments of the present invention, there are no other opaque carrier plates disposed between the encapsulated integrated circuit 20 and the transparent substrate 16.

In some embodiments of the present invention, the light-emitting element 30 overlaps with the electrode 20C on the front surface 20A of the encapsulated integrated circuit 20 when viewed from the vertical direction.

In some embodiments of the present invention, when viewed from the vertical direction, the light-emitting element 30 does not overlap with the electrode 20C on the front surface 20A of the encapsulated integrated circuit 20, and further comprises a wire 32 electrically connecting the light-emitting element 30 with the electrode 20C on the front surface 20A of the encapsulated integrated circuit 20.

In some embodiments of the present invention, the light-emitting element 30 includes a light-emitting diode.

The present invention is characterized in that the pins of the encapsulated integrated circuit (IC) are designed to the top and back surfaces of the encapsulated integrated circuit structure, and light-emitting elements (such as light-emitting diodes) are stacked on the encapsulated integrated circuit without occupying other space. Generally, the light-emitting element can be directly electrically connected to the pins of the encapsulated integrated circuit, so there is no need to form additional wires. According to the invention, the stacked structure of the encapsulated integrated circuit and the light-emitting element can be directly mounted on the transparent substrate, so that the opaque carrier plate is omitted, the occupied area of the element can be greatly reduced, and the total light transmittance of the transparent display panel can be obviously improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transparent display panel, comprising:
an encapsulated integrated circuit, wherein a front surface and a back surface of the encapsulated integrated circuit both contain a plurality of electrodes; and
a light-emitting element located on the front surface of the encapsulated integrated circuit, which partially overlaps with the encapsulated integrated circuit when viewed from a vertical direction and is electrically connected with the electrode on the front surface of the encapsulated integrated circuit.

2. The transparent display panel according to claim 1, further comprising a protective layer covering the front surface of the encapsulated integrated circuit and the light-emitting element.

3. The transparent display panel of claim 2, wherein the material of the protective layer comprises transparent silicone or epoxy resin.

4. The transparent display panel according to claim 1, further comprising a transparent substrate, and the back surface of the encapsulated integrated circuit is in direct contact with a plurality of transparent wires on the transparent substrate.

5. The transparent display panel of claim 4, wherein the material of the plurality of transparent wires comprises indium tin oxide.

6. The transparent display panel of claim 4, wherein there is no other opaque carrier plate disposed between the encapsulated integrated circuit and the transparent substrate.

7. The transparent display panel according to claim 1, wherein the light-emitting element overlaps with the electrode on the front surface of the encapsulated integrated circuit when viewed from the vertical direction.

8. The transparent display panel of claim 1, wherein the light-emitting element does not overlap with the electrode on the front surface of the encapsulated integrated circuit when viewed from the vertical direction, and further comprises a wire electrically connecting the light-emitting element and the electrode on the front surface of the encapsulated integrated circuit.

9. The transparent display panel according to claim 1, wherein the light-emitting element comprises a light-emitting diode.
